(19) United States
(12) Patent Application Publication
(10) Pub. No.: US 2022/0091513 A1
(43) Pub. Date: Mar. 24, 2022

(54) FILM STRUCTURE FOR ELECTRIC FIELD ASSISTED BAKE PROCESS

(71) Applicant: Applied Materials, Inc., Santa Clara, CA (US)

(72) Inventors: Mangesh Ashok BANGAR, San Jose, CA (US); Huixiong DAI, San Jose, CA (US); Pinkesh Rohit SHAH, San Jose, CA (US); Srinivas D. NEMANI, Sunnyvale, CA (US); Christopher S. NGAI, Burlingame, CA (US); Ellie Y. YIEH, San Jose, CA (US)

(21) Appl. No.: 17/025,282

(22) Filed: Sep. 18, 2020

(51) Int. Cl. G03F 7/38; H01L 21/027; H01L 21/311; G03F 7/11

(52) U.S. Cl. CPC G03F 7/38; G03F 7/11; H01L 21/31138; H01L 21/0274

(57) ABSTRACT

A film structure for an electric field assisted bake process and methods of forming and implementing such a film structure are described herein. An example is a method for semiconductor processing. A photoresist is deposited on an underlayer disposed on a substrate. The underlayer includes carbon. The photoresist is exposed to a pattern of electromagnetic radiation. After exposing the photoresist, an electric field assisted bake is performed on the photoresist.

### BACKGROUND

### Field

The present disclosure generally relates to methods and apparatuses for processing a substrate, and more specifically to methods and apparatuses for patterning photoresist.

### Description of the Related Art

Integrated circuits have evolved into complex devices that can include millions of components (e.g., transistors, capacitors and resistors) on a single chip. Photolithography may be used to form components on a chip. Generally the process of photolithography involves a few basic stages. Initially, a photoresist is formed on a substrate. The photoresist may be formed by, for example, spin-coating. The photoresist may include a resist resin, a photoacid generator, and a quencher. The photoacid generator, upon exposure to electromagnetic radiation in a subsequent exposure stage, alters the solubility of the photoresist in the development process.

In the exposure stage, a photomask or reticle may be used to selectively expose certain regions of a photoresist disposed on the substrate to electromagnetic radiation. Other exposure methods may be maskless exposure methods. Exposure to light may decompose the photoacid generator, which generates acid and results in a latent acid image in the resist resin. After exposure, the substrate may be heated in a post-exposure bake process. During the post-exposure bake process, the acid generated by the photoacid generator reacts with the resist resin in the photoresist, changing the solubility of the resist of the photoresist during a subsequent development process.

After the post-exposure bake, the substrate, and, particularly, the photoresist may be developed and rinsed. After development and rinsing, a patterned photoresist is then formed on the substrate. Openings through the patterned photoresist, after the development and rinse processes, expose the underlying target material for etching to transfer features onto the target material. However, inaccurate control or low resolution of the lithography exposure process may result in poor critical dimension of the photoresist, which can result in unacceptable line width roughness (LWR). Furthermore, during the exposure process, acid (generated from the photoacid generator) may randomly diffuse to any region, including the regions protected under the mask, unintended to be diffused, thus creating an undesired roughness profile at an edge of the patterned photoresist. Large line width roughness (LWR) and undesired profile of the patterned photoresist may result in inaccurate feature transfer to the target material, which can eventually lead to device failure and yield loss.

### SUMMARY

A film structure for an electric field assisted bake process and methods of forming and implementing such a film structure are described herein. An example is a method for semiconductor processing. A photoresist is deposited on an underlayer disposed on a substrate. The underlayer may include carbon. The photoresist is exposed to a pattern of electromagnetic radiation. After exposing the photoresist, an electric field assisted bake is performed on the photoresist.

Another example is a method for semiconductor processing. A photoresist is deposited on an underlayer disposed on a substrate. The underlayer is a material having an electrical resistance in a range from 9×10⁻⁶ Ω*cm to 10¹⁴ Ω*cm. The photoresist is exposed to a pattern of electromagnetic radiation. After exposing the photoresist, an electric field assisted bake is performed on the photoresist.

Another example is a method for semiconductor processing. A photoresist is exposed to a pattern of electromagnetic radiation. The photoresist is disposed on an underlayer. The underlayer is disposed on a substrate. The underlayer has a concentration of carbon in a range from 35 atomic percent to 45 atomic percent. After exposing the photoresist, an electric field assisted bake is performed on the photoresist.

A further example is a method for semiconductor processing. A bake is performed on a photoresist. The photoresist is disposed directly on an underlayer. The underlayer is disposed on a substrate. The underlayer has a concentration of carbon in a range from 35 atomic percent to 45 atomic percent. Performing the bake includes controlling a temperature of an environment in which the photoresist is disposed, and applying an electric field to the photoresist.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is to be noted, however, that the appended drawings illustrate only typical examples and are therefore not to be considered limiting of the scope of this disclosure, for the disclosure may admit to other equally effective examples.

FIG. 1 is a schematic of a simplified arrangement for an electric field assisted post-exposure bake of a photoresist according to some examples.

FIG. 2 is a chart illustrating a current supplied to an electrode to illustrate effects of different carbon concentrations of underlayers according to some examples.

FIG. 3 is a chart illustrating effects of electric field on underlayers with different carbon concentrations according to some examples.

FIG. 4 is a schematic of a processing chamber for processing a substrate according to some examples.

FIG. 5 depicts a flow diagram of a method for utilizing an underlayer disposed under a photoresist for an electric field assisted post-exposure bake process.

To facilitate understanding, identical reference numerals have been used, wherever possible, to designate identical elements that are common to the Figures. Additionally, elements of one example may be advantageously adapted for utilization in other examples described herein.

### DETAILED DESCRIPTION

A film structure for an electric field assisted bake process and methods of forming and implementing such a film structure are described herein. Generally, in some examples, an underlayer that includes carbon, such as having a concentration of carbon in a range between 0 atomic percent (at. %) and 100 at. %, and more particularly in a range from 35 at. % to 45 at. %, can be implemented with a photoresist. Generally, in some examples, an underlayer that has a desired electrical resistance, such as having an electrical resistance in a range between 9×10⁻⁶ Ω*cm and 10¹⁴ Ω*cm, and more particularly in any range from 9×10⁻⁶ Ω*cm to 15×10⁻⁶ Ω*cm, from 1 Ω*cm to 100 Ω*cm, or from 10⁶ Ω*cm to 10¹⁴ Ω*cm, can be implemented with a photoresist. The photoresist can be disposed directly on and contacting the underlayer. The photoresist can be exposed to a pattern of electromagnetic radiation and, subsequently, an electric field assisted bake can be performed on the photoresist. The underlayer can have increased adhesion with the photoresist, which can reduce pattern collapse, bending, and deformation of the photoresist through subsequent processes. The underlayer can also be used to tune the electric field implemented in the bake, which can improve sensitivity, a critical dimension, and pattern collapse of the photoresist. Although examples described herein are in the context of a post-exposure bake, other examples can be implemented in other bake processes, such as a pre-exposure bake.

Various different examples are described below. Although multiple features of different examples may be described together in a process flow or system, the multiple features can each be implemented separately or individually and/or in a different process flow or different system. Additionally, various process flows are described as being performed in an order; other examples can implement process flows in different orders and/or with more or fewer operations.

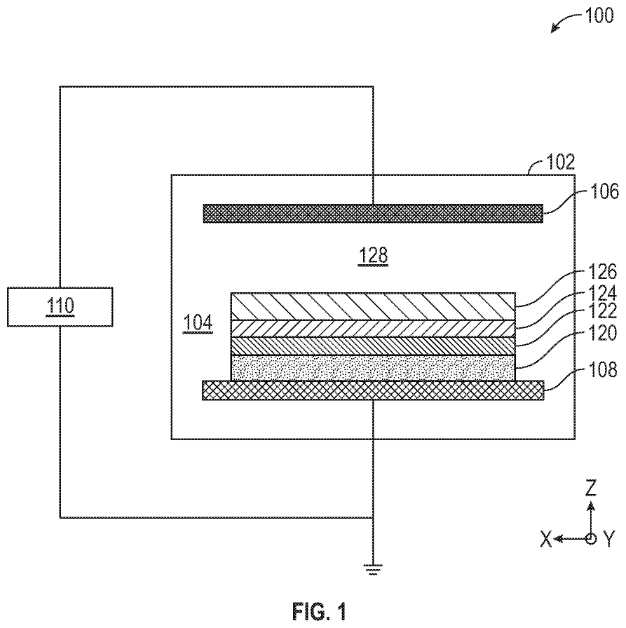

FIG. 1 is a schematic of a simplified arrangement 100 for an electric field assisted post-exposure bake of a photoresist according to some examples. The arrangement 100 is depicted as including a processing chamber 102. The processing chamber 102 has walls, a top, and a bottom that enclose an enclosed volume 104. The processing chamber 102 includes a top electrode 106 and a bottom electrode 108 both disposed within the enclosed volume 104. In some examples (and as detailed by a further example below), the bottom electrode 108 may be disposed within a substrate support assembly, such as an electrostatic and/or vacuum chuck. The top electrode 106 and bottom electrode 108 are electrically coupled to and between a power source 110. The power source 110 can be or include any appropriate power source configured to generate an electric field between the top electrode 106 and the bottom electrode 108. The power source 110 can include any direct current (DC) and/or alternating current (AC) power source, and can include any voltage source and/or current source. In some examples, the power source 110 is or includes a DC voltage source, which may generate a pulsed DC voltage, having a positive terminal electrically coupled to the bottom electrode 108 and a ground node, and having a negative terminal electrically coupled to the top electrode 106. Additionally, although not illustrated in FIG. 1 for clarity, the processing chamber 102 can include thermal elements for performing an electric field assisted post-exposure bake, as detailed in a further example below. Further, although not illustrated in FIG. 1 for clarity, the processing chamber 102 can include one or more fluid sources and/or vacuum pumping and/or exhaust components to provide one or more fluids and/or control a pressure in the enclosed volume 104 during the electric field assisted post-exposure bake.

A substrate 120 is disposed on the bottom electrode 108. The substrate 120 can be or include any appropriate semiconductor substrate, such as a bulk substrate, semiconductor-on-insulator (SOI) substrate, or the like. The semiconductor substrate can be or include any appropriate semiconductor material, such as silicon, silicon germanium, gallium nitride, gallium arsenide, or the like, for example. In some examples, the semiconductor substrate is a bulk silicon wafer. Examples of substrate sizes include 200 mm diameter, 300 mm diameter, 400 mm diameter, and 450 mm diameter, among others. The substrate 120 can further include other layers or materials formed on the semiconductor substrate. For example, materials for gate structures and source/drain regions of transistors can be formed on and/or in the semiconductor substrate, and various dielectric layers, such as inter-layer dielectrics (ILDs), inter-metallization dielectrics (IMDs), etch stop layers, or the like, which may further include metal lines and/or vias, can be formed on the semiconductor substrate. In some examples herein, the substrate 120 includes some layer or material that is to be etched using a lithography processes that patterns a photoresist according to the pattern to be etched into the layer or material.

A film structure is disposed on the substrate 120. The film structure includes a hardmask 122, an underlayer 124, and a photoresist 126. The hardmask 122 is disposed on the substrate 120. The hardmask 122 can be or include any appropriate material for a hardmask implemented in an etching process. As examples, the hardmask 122 can be or include silicon nitride, titanium nitride, amorphous carbon, silicon oxynitride, or any other appropriate material. The hardmask 122 can further include a single layer or multiple layers of differing material. The hardmask 122 can be formed on the substrate 120 using, for example, any appropriate deposition process, such as chemical vapor deposition (CVD), physical vapor deposition (PVD), spin-on, or the like.

The underlayer 124 is disposed on the hardmask 122. In some examples, the underlayer 124 is a carbon-containing layer. The carbon-containing underlayer can include a concentration of carbon between a trace amount of carbon (e.g., greater than an incidental amount of carbon that is formed in a layer due to processing) and a completely carbon layer. For example, the concentration of carbon in the carbon-containing underlayer can be in a range greater than approximately 0 atomic percent (at. %) and less than approximately 100 at. %. More particularly, in some examples, the concentration of carbon in the carbon-containing underlayer can be in a range from 35 at. % to 45 at. %. The underlayer 124 can be any carbon-containing material. In some examples, the underlayer 124 can be silicon oxycarbide (SiOC), silicon oxycarbon nitride (SiOCN), silicon carbon nitride (SiCN), a Sp2 carbon-containing material, a Sp3 carbon-containing material, a carbon-containing metal (e.g., tungsten carbide (WC)) (which can further be doped by other dopants, such as silicon), or the like.

In some examples, the underlayer 124 is any material layer having a desired electrical resistance. The underlayer 124 can be a material having an electrical resistance in a range between 9×10⁻⁶ Ω*cm and 10¹⁴ Ω*cm. In some examples, the underlayer 124 can be a metal (or metal-containing) material having a resistance in a range from 9×10⁻⁶ Ω*cm to 15×10⁻⁶ Ω*cm. An example metal or metal-containing material includes tungsten (W). In some examples, the underlayer 124 can be a semiconductor material, which may be doped, having a resistance in a range from 1 Ω*cm to 100 Ω*cm. An example semiconductor material includes silicon (Si), which may be amorphous or polycrystalline, and which may be doped or undoped. In some examples, the underlayer 124 can be a dielectric material having a resistance in a range from 10⁶ Ω*cm to 10¹⁴ Ω*cm. Example dielectric materials include oxycarbide (SiOC), silicon oxycarbon nitride (SiOCN), silicon oxynitride (SiON), silicon nitride (SiN), silicon carbon nitride (SiCN), or the like.

The underlayer 124 can be deposited by CVD, atomic layer deposition (ALD), PVD, spin-on, or the like. As will be explained further below, the underlayer 124 can enable improvements to the lithography and subsequent etching processes that use a photoresist formed on the underlayer 124.

The photoresist 126 is disposed on the underlayer 124. As illustrated, the photoresist is disposed directly on and contacting the underlayer 124. The photoresist 126 can be any appropriate photosensitive material, such as a chemically amplified resist (CAR) or a metal/metal oxide containing resist, and may further be a positive tone or negative tone photoresist. In some examples, the photoresist 126 is a positive tone photoresist. The photoresist 126 can be deposited on the underlayer 124 by spin-on, spray coating, or the like, for example. Prior to the electric field assisted post-exposure bake performed in the processing chamber 102, the photoresist 126 is exposed to electromagnetic radiation, such as light, and more particularly, such as ultraviolet (UV) light, extreme UV (EUV) light, or the like. The exposure exposes the photoresist 126 to a pattern corresponding to a pattern to be formed in the photoresist.

An interface region 128 is in the enclosed volume 104 between the photoresist 126 (as disposed on the substrate 120, which is supported by and disposed on the bottom electrode 108) and the top electrode 106. In some examples, a fluid (e.g., a gas or liquid) can be disposed in and/or flowed through the interface region 128 (and further, in the enclosed volume 104), and in other examples, the interface region 128 (and further, the enclosed volume 104) can be at a vacuum.

Following exposure of the photoresist 126, an electric field assisted post-exposure bake is performed on the photoresist 126 with the substrate 120 disposed in the enclosed volume 104 in the processing chamber 102 and disposed on the bottom electrode 108. The processing chamber 102 includes thermal components, such as a heater, for performing the electric field assisted post-exposure bake, an example of which is described in detail below. The electric field assisted post-exposure bake includes controlling a temperature of the substrate 120 with the photoresist 126 thereon and/or controlling a temperature of the environment (e.g., within the enclosed volume 104) in which the substrate 120 with the photoresist 126 thereon is disposed. Controlling the temperature can include raising or increasing a temperature of the environment within the enclosed volume 104 and/or a temperature of the substrate 120 with the photoresist 126 to some specified temperature. While the temperature is being controlled (e.g., while the temperature is being raised or increased, and/or while the temperature is elevated), an electric field is generated between the top electrode 106 and the bottom electrode 108.

The electric field is provided between the top electrode 106 and the bottom electrode 108 during the electric field assisted post-exposure bake. In the illustrated example, the top electrode 106 and bottom electrode 108 generally form a parallel plate capacitor, and hence, the electric field generated between the top electrode 106 and bottom electrode 108 is generally consistent with principles of an electric field of a parallel plate capacitor. In the illustrated example of FIG. 1, the electric field is provided in a direction normal to the opposing, facing surfaces of the top electrode 106 and the bottom electrode 108, which is in a +/− Z-direction. Hence, with the substrate 120 (and photoresist 126 disposed thereon) disposed on the bottom electrode 108 in the configuration of FIG. 1, the electric field is in a direction normal to a major surface (e.g., on which the film structure is disposed) of the substrate 120. Lateral dimensions of the top electrode 106 and bottom electrode 108 are greater than the lateral dimension of the substrate 120 such that non-uniform edge effects of an electric field generated between the top electrode 106 and bottom electrode 108 generally do not impinge on the photoresist 126.

The electric field can control migration and diffusion of an electrically charged species (e.g., ions, electrons, etc.) in the photoresist 126. For example, photoacid is generated in regions of the photoresist 126 when photoacid generator (PAG) is exposed to the electromagnetic radiation during the exposure. In the absence of intervening forces, movement and diffusion of photoacid is generally random or isometric. Further, due to random lateral movement and diffusion (e.g., in a direction parallel to a planar surface of the substrate 120, which is in an X-Y plane in FIG. 1), photoacid may not have a clear boundary at an interface between an exposed region and an unexposed region of the photoresist 126. As such, lateral movement of photoacid into unexposed regions of the photoresist 126 may result in line edge roughness, resolution loss, photoresist footing loss, and/or profile deformation. Such adverse effects can cause inaccurate feature transfer to the underlying target layer, which can cause a defective device and/or eventually lead to device failure. By providing the electric field, movement and diffusion of charged species in the photoresist 126, such as photoacid, can be substantially confined within a direction of the electric field. This electric field attracts or repels charged species in a +/− Z-direction, which can prevent or reduce lateral movement of the charged species in an X-direction and/or Y-direction. Anisometric movement and diffusion of charged species (e.g., photoacid) can be confined in the Z-direction, without substantial movement or diffusion in an X-direction and/or Y-direction. By confining movement and diffusion of charged species in such a manner, line edge roughness, resolution, photoresist footing, and/or profiles in the photoresist 126 can be improved.

Implementing an underlayer 124 that is carbon-containing and/or has a desired electrical resistance, as described above, can improve adhesion, sensitivity, a critical dimension, and/or pattern collapse of the photoresist 126. A carbon-containing underlayer can have a hydrophobic surface (e.g., before the photoresist is deposited on the underlayer). The hydrophobic surface can form bonds with the photoresist 126 that are affected less by the electric field. Hence, bonds between the carbon-containing underlayer 124 and the photoresist 126 can remain stronger during the electric field assisted post-exposure bake permitting improved adhesion. The improved adhesion can lead to reduced pattern collapse, bending, and deformation of the photoresist 126 through subsequent processes.

The underlayer 124 can also be used to tune the electric field implemented in the electric field assisted post-exposure bake, which can improve sensitivity and a critical dimension of the photoresist 126. The electric field is a function of the voltage difference between the top electrode 106 and bottom electrode 108 and the distance between the top electrode 106 and bottom electrode 108. In some examples, varying the carbon concentration in the carbon-containing underlayer varies the dielectric value (k-value) of the carbon-containing underlayer, which in turn varies the capacitance between the top electrode 106 and bottom electrode 108. In some examples, varying the resistance of the underlayer varies a parasitic resistance in the processing environment.

Varying this capacitance and/or the resistance of the underlayer changes the electrical response of the arrangement 100 to, e.g., a pulsed DC voltage supplied by the power source 110. Changing the capacitance and/or resistance changes the time constant (e.g., a resistance-capacitance (RC) time constant, inductance-resistance (L/R) time constant, or some combination thereof) of the arrangement 100 that indicates how charge accumulates at the electrodes 106, 108 when the DC voltage is pulsed. How the charge accumulates, and accordingly, how the voltage difference between the electrodes 106, 108 changes, affects the electric field. Tuning the electric field can permit better confinement of photoacid in the photoresist 126. This better confinement can increase sensitivity of the photoresist 126 to a dosage of the electromagnetic radiation, and hence, with an increased sensitivity, a lower dosage can be used in the exposure. Additionally, better confinement can permit more precise patterning because of reduced lateral movement or diffusion, which can permit a reduced critical dimension.

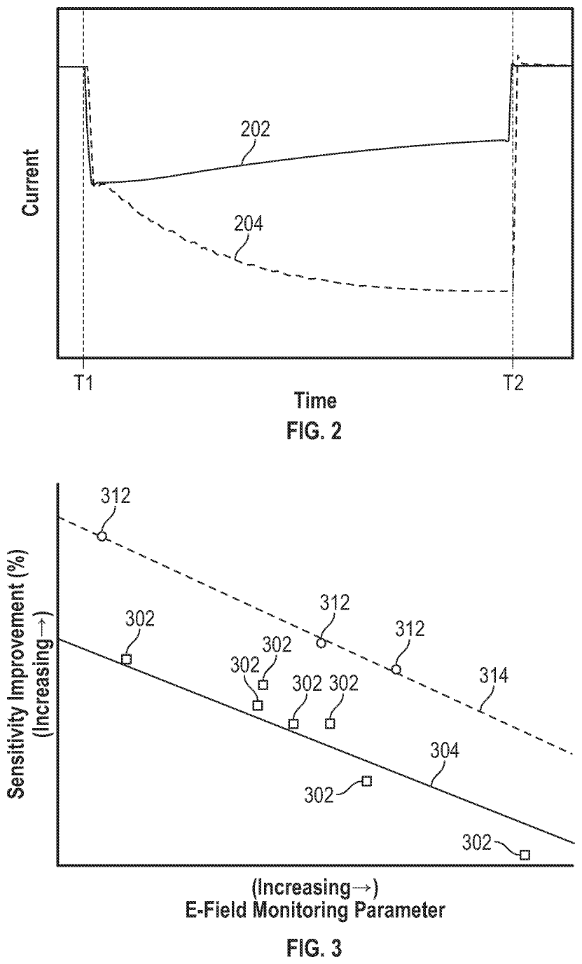

FIG. 2 is a chart illustrating a current supplied to an electrode to illustrate effects of different carbon concentrations of underlayers. The chart of FIG. 2 shows current supplied to an electrode (e.g., a top electrode) when a negative DC voltage is pulsed starting at time T1 and ending at time T2. Current response 202 is for an underlayer that has a higher carbon concentration than the underlayer that has current response 204. Current response 204 is generally more negative than current response 202, and hence, a magnitude of the current response 204 is greater than a magnitude of the current response 202. The processing environment in which the substrate and photoresist are baked can be an electrically leaky environment. The underlayer can affect the extent of leakage in the environment. As indicated by FIG. 2, an underlayer with a higher carbon concentration can increase the impedance of the leaky environment, which can reduce a magnitude of the current through the environment, as indicated by current response 202. Similarly, an underlayer with a lower resistance can reduce the impedance and increase leakage in the environment, while conversely, an underlayer with a higher resistance can increase the impedance and decrease leakage in the environment. A higher current through the leaky environment can dissipate charge accumulated on electrodes, which can reduce an electric field.

FIG. 3 is a chart illustrating effects of electric field on underlayers with different carbon concentrations. First plot points 302 correspond to substrates with underlayers and photoresist (as shown in FIG. 1) that undergo an electric field assisted post-exposure bake, where the underlayers have a same carbon concentration, which is in a range from 35 at. % to 45 at. %. The substrates of the first plot points 302 were processed with respective electric field assisted post-exposure bakes that implemented differing the electric field conditions, which are generally referred to as an electric field (E-Field) monitoring parameter. The E-Field monitoring parameter can be any or a combination of electric field strength, voltage difference between electrodes, distance between electrodes, duration or duty cycle of the supplied voltage, or the like. The sensitivity improvement of these substrates was then determined relative to like substrates and photoresists without the applied electric field that undergoes the same processing. The sensitivity improvement is the difference in dosage to print a feature in photoresist between instances with and without the applied electric field, which difference is expressed as a percentage of the dosage to print the feature in photoresist without the applied electric field. A first fitted line 304 is extrapolated to fit the first plot points 302.

Similarly, second plot points 312 correspond to substrates with underlayers and photoresist (as shown in FIG. 1) that undergo an electric field assisted post-exposure bake, where the underlayers have a same carbon concentration, which is in a range from 35 at. % to 45 at. %. The substrates of the second plot points 312 were processed with respective electric field assisted post-exposure bakes that implemented differing the electric field conditions. The sensitivity improvement of these substrates was then determined relative to like substrates and photoresists without the applied electric field that undergoes the same processing. A second fitted line 314 is extrapolated to fit the second plot points 312.

The underlayers on substrates that correspond to the first plot points 302 have a carbon concentration that is higher than the carbon concentration of the underlayers on substrates that correspond to the second plot points 312. As shown by the chart of FIG. 3 carbon concentration of the underlayer can affect the sensitivity of the photoresist. Generally, a lower carbon concentration can result in increased sensitivity of the photoresist.

Concentration of carbon in the underlayer can affect the critical dimension of the feature formed in the photoresist. Although carbon-containing underlayers (e.g., with a concentration of carbon in a range from 35 at. % to 45 at. %) generally can enable improved critical dimensions, higher concentrations of carbon in an underlayer can permit lower minimum critical dimensions compared to lower concentrations of carbon in an underlayer. Accordingly, implementing a concentration of carbon in an underlayer can balance considerations of sensitivity and minimum critical dimensions for a given application. For example, for applications where minimum critical dimension may be more important than sensitivity, a higher concentration of carbon (e.g., approaching 45 at. %) in an underlayer may be desirable, whereas for applications where sensitivity may be more important than minimum critical dimension, a lower concentration of carbon (e.g., approaching 35 at. %) in an underlayer may be desirable. Any balance of considerations, including other factors, may be used.

Electrical resistance of the underlayer 124 can affect the sensitivity of the photoresist and pattern collapse. A higher current in the environment has been observed to improve sensitivity but with potential increased pattern collapse of the photoresist. A lower current in the environment has been observed to improve pattern collapse but with lesser sensitivity. Accordingly, implementing a resistance of an underlayer 124 can balance considerations of sensitivity and pattern collapse for a given application. For example, for applications where concerns for pattern collapse may be more important than sensitivity, a higher resistance of an underlayer 124, which results in lower current, may be desirable, whereas for applications where sensitivity may be more important than concerns for pattern collapse, a lower resistance of an underlayer 124, which results in higher current, may be desirable. Any balance of considerations, including other factors, may be used.

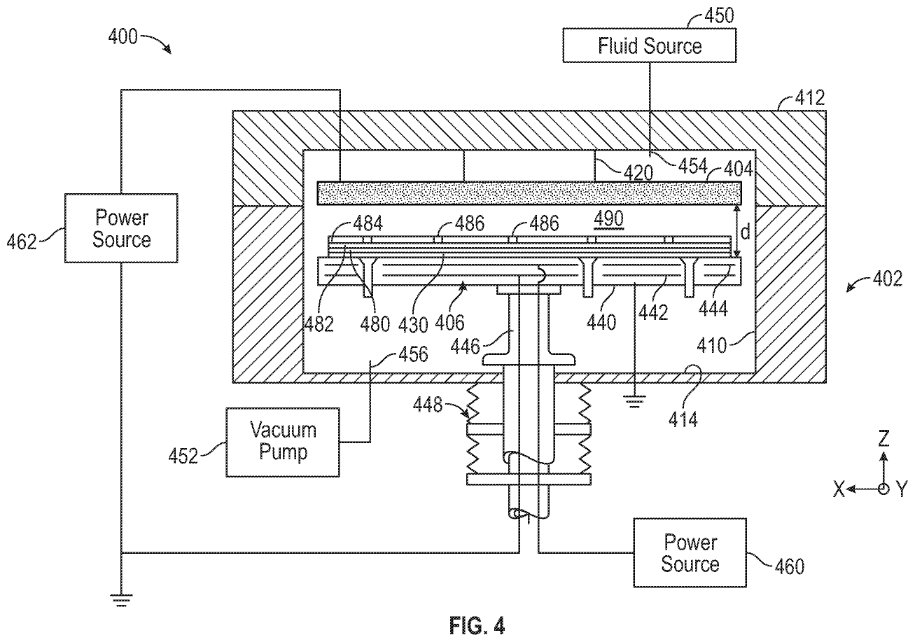

FIG. 4 is a schematic of a processing chamber 400 for processing a substrate according to some examples. The processing chamber 400 may be an independent stand-alone processing chamber. Alternatively, the processing chamber 400 may be part of a processing system, such as, for example, an in-line processing system, a cluster processing system, or a track processing system. The processing chamber 400 is described in detail below and may be used for an electric field assisted post-exposure bake.

The processing chamber 400 includes chamber walls 402, a top electrode 404, and a substrate support assembly 406. The chamber walls 402 include sidewalls 410, a lid assembly 412, and a bottom 414. The chamber walls 402 at least partially enclose an enclosed processing volume. The top electrode 404 can be or include a conductive material, such as a metal or doped semiconductor. Example conductive materials include doped silicon (e.g., doped polysilicon), molybdenum, aluminum, copper, silver, platinum, gold, palladium, zinc, or a mixture or alloy thereof. The top electrode 404 is mechanically coupled to the lid assembly 412. In the illustrated example, the top electrode 404 is mechanically coupled to the lid assembly 412 by an actuator 420. The actuator 420 is configured to extend and retract such that a distance d between the top electrode 404 and the substrate support assembly 406 can be varied. In other examples, the actuator can be omitted, and the top electrode 404 can be fixedly coupled to the lid assembly 412 (e.g., by a fixed stem).

The substrate support assembly 406 is centrally disposed within the processing chamber 400. The substrate support assembly 406 is configured to support a substrate 430 during processing. The substrate support assembly 406 may comprise a body 440 that encapsulates a bottom electrode 442 and at least one embedded heater 444. In some examples, the substrate support assembly 406 may be an electrostatic and/or vacuum chuck. The body 440 can be or include a dielectric material, such as silicon oxide, aluminum oxide, aluminum nitride, or other dielectric material. The body 440 is electrically insulative to electrically isolate the bottom electrode 442 and heater 444 encapsulated in the body, and is thermally conductive to permit thermal energy to propagate from the heater 444 to the substrate 430 on the substrate support assembly 406. The material of the body 440 can affect a capacitance formed between the top electrode 404 and the bottom electrode 442. The bottom electrode 442 can be or include a conductive material, such as a metal or doped semiconductor. Example conductive materials include doped silicon (e.g., doped polysilicon), molybdenum, aluminum, copper, silver, platinum, gold, palladium, zinc, or a mixture or alloy thereof. The heater 444, such as a resistive element, is disposed in the body 440 of the substrate support assembly 406. The heater 444 controllably heats the substrate support assembly 406 and the substrate 430 positioned thereon to a predetermined temperature. The heater 444 is configured to quickly ramp the temperature of the substrate 430 and to accurately control the temperature of the substrate 430. Furthermore, it is noted that the heater 444 may additionally or alternatively be disposed at other locations of the processing chamber 400, such as on or embedded in a chamber wall, chamber liner, edge ring that circumscribes the substrate, the chamber lid, top electrode, and the like to provide thermal energy to the substrate 430 disposed on the substrate support assembly 406.

Generally, the substrate support assembly 406 is mechanically coupled to and supported by a stem 446. The stem 446 is coupled to a lift system (not shown) for moving the substrate support assembly 406 between an elevated processing position (as shown) and a lowered substrate transfer position. The lift system may accurately and precisely control the position of the substrate 430 in the Z-direction. In some examples, the lift system may also be configured to move the substrate 430 in the X-direction, the Y-direction, or the X-direction and the Y-direction. A bellows 448 is coupled to the substrate support assembly 406 to provide a vacuum seal between the volume enclosed by the chamber walls 402 and the atmosphere outside the processing chamber 400 and to facilitate movement of the substrate support assembly 406 in the Z-direction.

In some examples, the substrate support assembly 406 may be configured to rotate. In some examples, the substrate support assembly 406 is configured to rotate about the Z-axis. The substrate support assembly 406 may be configured to continuously or constantly rotate, or the substrate support assembly 406 may be configured to rotate in a step-wise or indexing manner. For example, the substrate support assembly 406 may rotate a predetermined amount, such as 90°, 180°, or 270°, and then rotation may stop for a predetermined amount of time.

The processing chamber 400 includes or is fluidly coupled to a fluid control system. The fluid control system includes a fluid source 450 and a vacuum pump 452. The processing chamber 400 includes an inlet 454 through which the fluid source 450 is fluidly coupled to the enclosed volume of the processing chamber 400. The inlet 454 can be through a chamber wall 402, such as disposed through any one of the lid assembly 412, sidewalls 410, or bottom 414. In the illustration of FIG. 4, the inlet 454 is disposed through the lid assembly 412. The processing chamber 400 further includes a pumping port 456 through which the vacuum pump 452 is fluidly coupled to the enclosed volume of the processing chamber 400. The pumping port 456 can be through a chamber wall 402, such as disposed through any one of the lid assembly 412, sidewalls 410, or bottom 414. In the illustration of FIG. 4, the pumping port 456 is disposed through the bottom 414.

The fluid source 450 is configured to deliver a fluid (e.g., a gas) to the enclosed volume of the processing chamber 400 through the inlet 454, optionally at a controlled temperature. The fluid can be any one or more of any appropriate gas or mixture of gases or any other fluid. The vacuum pump 452 is configured to exhaust a fluid and/or pump down a pressure in the enclosed volume of the processing chamber 400 through the pumping port 456. The fluid source 450 and/or vacuum pump 452 (through the inlet 454 and pumping port 456) can be configured to pressurize the enclosed volume of the processing chamber 400 and/or to create a controlled environment within the enclosed volume of the processing chamber 400.

The processing chamber 400 includes or is electrically coupled to power sources 460, 462. The heater 444 encapsulated in the body 440 of the substrate support assembly 406 is electrically coupled to the power source 460. The power source 460 supplies electrical power to the heater 444 that the heater 444 converts to thermal energy (e.g., by resistive elements). The heater 444 can therefore control a temperature of the substrate 430 on the substrate support assembly 406. The top electrode 404 and the bottom electrode 442 are electrically coupled to the power source 462. The power source 462 supplies electrical power to the top electrode 404 and bottom electrode 442 to generate an electric field in a Z-direction between the top electrode 404 and bottom electrode 442. The stem 446 can provide a conduit for electrical and/or thermocouple leads between the substrate support assembly 406 and other components, such as the power sources 460, 462. The conduit can enable movement of the substrate support assembly 406 as described above. The body 440 of the substrate support assembly 406 is electrically coupled to a ground node, which may dissipate any charge that accumulates on the body 440. Additionally, the power sources 460, 462 or another power source can be electrically coupled to other components of the processing chamber 400 to provide electrical power for operation of those components.

The power source 462 is configured to supply, for example, between about 500 V and about 100 kV to generate an electric field having a strength between about 0.1 MV/m and about 100 MV/m between the top electrode 404 and the bottom electrode 442. In some examples, the power source 462 is a pulsed DC power source. The pulsed DC voltage supplied by the power source 462 may be from a half-wave rectifier or a full-wave rectifier. The pulsing of the DC voltage may have a frequency of between about 10 Hz and 1 MHz. The duty cycle of the pulsed DC voltage may be from between about 5% and about 95%, such as between about 20% and about 60%, and more particularly, between about 20% and about 40%. The rise and fall time of the pulsed DC voltage may be between about 1 ns and about 1000 ns, such as between about 10 ns and about 500 ns, and more particularly, between about 10 ns and about 100 ns. In some examples, the power source 462 is or can include an AC power supply, a DC power supply, or a combination thereof.

In some examples, the power source 462 may use a DC voltage offset. The DC voltage offset may be, for example, between about 0% and about 75% of the applied voltage, such as between about 5% and about 60% of the applied voltage. In some examples, the top electrode 404 is pulsed negatively while the bottom electrode 442 is also pulsed negatively. In these examples, the pulsing of applied voltages to the top electrode 404 and the bottom electrode 442 are synchronized but offset in time. For example, the top electrode 404 may be at a negative applied voltage pulse state while the bottom electrode 442 is at a zero applied voltage state, and vice versa.

As illustrated in FIG. 4, a substrate 430 is disposed on and supported by the body 440 of the substrate support assembly 406. The enclosed volume of the processing chamber 400 is accessed through a substrate transfer port (not shown) disposed through a chamber wall 402 (e.g., a sidewall 410) and configured to facilitate movement of the substrate 430 into and out of the processing chamber 400. In some examples where the processing chamber 400 is part of a processing system, the substrate transfer port may allow for the substrate 430 to be transferred to and from an adjoining transfer chamber.

A film structure is disposed on the substrate 430. The film structure includes a hardmask 480, an underlayer 482, and a photoresist 484. The hardmask 480 is disposed on the substrate 430. The underlayer 482 is disposed on the hardmask 480. The photoresist 484 is disposed on the underlayer 482. The substrate 430, hardmask 480, underlayer 482, and photoresist 484 can be configured, can include materials, and/or be formed as described above with respect to the substrate 120, hardmask 122, underlayer 124, and photoresist 126, respectively, above.

The photoresist 484 disposed on the substrate 430 has been previously exposed, prior to being transferred into the processing chamber 400, to electromagnetic radiation in an exposure stage of a photolithography process. The photoresist 484 has latent image features 486 formed therein from the exposure stage. The latent image features 486 are regions of the photoresist 484 that are to remain, e.g., after a development stage of a photolithography process. Depending on whether the photoresist 484 is a positive or negative tone photoresist, the latent image features 486 may be regions of the photoresist 484 that were exposed or not exposed in the exposure stage.

The substrate 430 is positioned on the body 440 of the substrate support assembly 406 such that interfaces between exposed and unexposed portions of the photoresist (e.g., to-be formed sidewalls of the latent image features 486) are parallel to the electric field generated between the top electrode 404 and bottom electrode 442. Charged species in the photoresist 484 are affected by the electric field as described above. The top electrode 404 and bottom electrode 442 generally form a parallel plate capacitor. The electric field generated between the top electrode 404 and bottom electrode 442 is in a Z-direction.

The electric field between the top electrode 404 and bottom electrode 442 can be varied or controlled in a number of ways. Generally, electric field generated by a parallel plate capacitor is a function of a voltage difference and distance between the parallel plates. The voltage difference between the top electrode 404 and bottom electrode 442 can be controlled by controlling the voltage supplied by the power source 462 and controlling the effective capacitance between the top electrode 404 and bottom electrode 442 with other impedance(s) of the processing chamber 400. The voltage difference between the top electrode 404 and bottom electrode 442 is a function of the voltage supplied by the power source 462 and the impedance of the circuit of the processing chamber 400. The impedance is determined in part by the effective capacitance between the top electrode 404 and bottom electrode 442. The effective capacitance is determined at least in part by materials disposed between the top electrode 404 and bottom electrode 442. Hence, a material of the underlayer 482 and a fluid (e.g., gas) flowed from the fluid source 450 and in an interface region 490 between the top electrode 404 and bottom electrode 442 (among other materials) can determine a capacitance between the top electrode 404 and bottom electrode 442. Further, the distance between the top electrode 404 and bottom electrode 442 can be varied by the actuator 420 and/or the substrate support assembly 406 to move the top electrode 404 and/or bottom electrode 442, respectively.

An electric field assisted post-exposure bake is performed in the photoresist 484 disposed in the processing chamber 400. The power source 460 supplies electrical power to the heater 444, which generates thermal energy that heats the substrate 430 and photoresist 484 disposed thereon. Supplying the electrical power from the power source 460 controls the temperature of the substrate 430 and photoresist 484. While the temperature is being controlled (e.g., while the temperature is being raised or increased, and/or while the temperature is elevated), an electric field is generated between the top electrode 404 and the bottom electrode 442 by the power source 462 supplying electrical power to the electrodes 404, 442. Any appropriate temperature, magnitude of electric field, and duration of the elevated temperature and applied electric field can be implemented.

After the electric field assisted post-exposure bake is performed, the substrate 430 can be transferred from the enclosed volume of the processing chamber 400 in a similar manner that the substrate 430 was transferred into the enclosed volume of the processing chamber 400. Subsequent processing can be performed on the substrate 430.

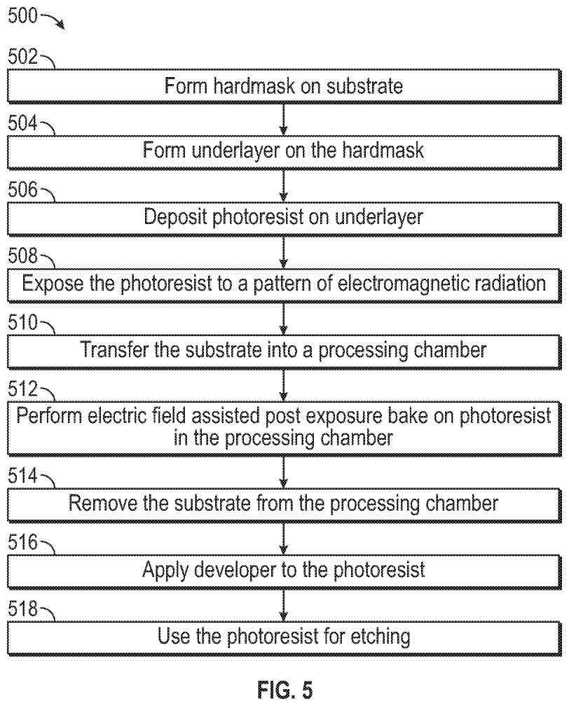

FIG. 5 depicts a flow diagram of a method 500 for utilizing an underlayer disposed under a photoresist for an electric field assisted post-exposure bake process. At block 502, a hardmask is formed on a substrate. The hardmask can be formed as described above with respect to the hardmask 122 of FIG. 1. The substrate can be like the substrate 120 of FIG. 1. At block 504, an underlayer is formed on the hardmask. The underlayer can be formed as described above with respect to the underlayer 124 of FIG. 1. At block 506, a photoresist is deposited on the underlayer. The photoresist can be like the photoresist 126 of FIG. 1 and can be deposited by spin-on, spray coating, or the like. At block 508, the photoresist is exposed to a pattern of electromagnetic radiation (e.g., UV light, EUV light, etc.).

At block 510, the substrate (with the underlayer and photoresist disposed thereon) is transferred into a processing chamber. For example, the substrate can be transferred into an enclosed volume of the processing chamber 400 and disposed on and supported by the substrate support assembly 406, as illustrated in and described above with respect to FIG. 4.

At block 512, an electric field assisted post-exposure bake is performed on the photoresist in the processing chamber. A heater in the processing chamber can bring the substrate up to a specified temperature for the bake process. For example, as in FIG. 4, the heater 444 with the power source 460 can generate thermal energy that can bring the substrate and/or an environment within the enclosed volume of the processing chamber 400 to a specified temperature. During the bake, an electric field is provided. For example, as in FIG. 4, the electric field can be between the top electrode 404 and bottom electrode 442 and can be controlled by a voltage applied by the power source 462, a fluid from the fluid source 450 flowed through the interface region 490, a distance between the top electrode 404 and bottom electrode 442, and a material of the underlayer, among others.

At block 514, the substrate is removed from the processing chamber. At block 516, a developer is applied to the photoresist to develop the photoresist. The photoresist thereafter is patterned with features corresponding to the exposure at block 508. At block 518, the photoresist is used for an etching process, such as to etch the hardmask. The etch can be any appropriate etch process, such as a dry plasma etch process like a reactive ion etch (RIE).

While the foregoing is directed to examples of the present disclosure, other and further examples of the disclosure may be devised without departing from the basic scope thereof, and the scope thereof is determined by the claims that follow.

What is claimed is:

1. A method for semiconductor processing, the method comprising:
depositing a photoresist on an underlayer disposed on a substrate, the underlayer including carbon;
exposing the photoresist to a pattern of electromagnetic radiation; and
after exposing the photoresist, performing an electric field assisted bake on the photoresist.

2. The method of claim 1, wherein the underlayer has a concentration of carbon in a range from 35 atomic percent to 45 atomic percent.

3. The method of claim 1, wherein the underlayer is silicon oxycarbide (SiOC), silicon oxycarbon nitride (SiOCN), silicon carbon nitride (SiCN), a Sp2 carbon-containing material, a Sp3 carbon-containing material, a carbon-containing metal, or a combination thereof.

4. The method of claim 1, wherein performing the electric field assisted bake includes:
controlling a temperature of an environment in which the photoresist is disposed; and
contemporaneously with controlling the temperature, applying an electric field to the photoresist.

5. The method of claim 4, wherein the electric field is applied between a first electrode and a second electrode, the photoresist being disposed between the first electrode and the second electrode during performing the electric field assisted bake.

6. The method of claim 4, wherein the electric field is normal to a major surface of the substrate on which the photoresist is disposed.

7. The method of claim 1, wherein, prior to depositing the photoresist, a surface of the underlayer on which the photoresist is deposited is hydrophobic.

8. The method of claim 1 further comprising:
after performing the electric field assisted bake, applying a developer to the photoresist; and
after applying the developer, using the photoresist in an etch process.

9. A method for semiconductor processing, the method comprising:
depositing a photoresist on an underlayer disposed on a substrate, the underlayer being a material having an electrical resistance in a range from 9×10⁻⁶ Ω*cm to 10¹⁴ Ω*cm;
exposing the photoresist to a pattern of electromagnetic radiation; and
after exposing the photoresist, performing an electric field assisted bake on the photoresist.

10. The method of claim 9, wherein the material of the underlayer has an electrical resistance in a range from 9×10⁻⁶ Ω*cm to 15×10⁻⁶ Ω*cm.

11. The method of claim 10, wherein the material of the underlayer is a metal or metal-containing material.

12. The method of claim 9, wherein the material of the underlayer has an electrical resistance in a range from 1 Ω*cm to 100 Ω*cm.

13. The method of claim 12, wherein the material of the underlayer is a semiconductor material.

14. The method of claim 9, wherein the material of the underlayer has an electrical resistance in a range from 10⁶ Ω*cm to 10¹⁴ Ω*cm.

15. The method of claim 14, wherein the material of the underlayer is a dielectric material.

16. A method for semiconductor processing, the method comprising:
performing a bake on a photoresist, the photoresist being disposed directly on an underlayer, the underlayer being disposed on a substrate, the underlayer having a concentration of carbon in a range from 35 atomic percent to 45 atomic percent, performing the bake comprising:
controlling a temperature of an environment in which the photoresist is disposed; and
applying an electric field to the photoresist.

17. The method of claim 16, wherein the underlayer is silicon oxycarbide (SiOC), silicon oxycarbon nitride (SiOCN), silicon carbon nitride (SiCN), a Sp2 carbon-containing material, a Sp3 carbon-containing material, a carbon-containing metal, or a combination thereof.

18. The method of claim 16, wherein the electric field is applied between parallel electrodes, the photoresist being disposed between the parallel electrodes during performing the electric field assisted bake.

19. The method of claim 16, wherein the electric field is normal to a major surface of the substrate.

20. The method of claim 16 further comprising:
exposing the photoresist to a pattern of electromagnetic radiation, performing the bake being after exposing the photoresist.
